(19) United States
(12) Patent Application Publication
(10) Pub. No.: US 2006/0065985 A1
(43) Pub. Date: Mar. 30, 2006

(54) Substrate edge scribe

(76) Inventors: Michael J. Berman, West Linn, OR (US); Bruce J. Whitefield, Camas, WA (US)

Correspondence Address: LSI LOGIC CORPORATION, 1621 BARBER LANE, MS: D-106, MILPITAS, CA, 95035, US

(21) Appl. No.: 10/956,003

(22) Filed: Sep. 30, 2004

(51) Int. Cl. H01L 23/544

(52) U.S. Cl. 257/797; 257/E23.179

(57) ABSTRACT

A substrate that is adapted for the fabrication of integrated circuits, having an improved scribe mark. The scribe mark is small enough to fit within an edge exclusion zone of the substrate, is disposed wholly within the edge exclusion zone of the substrate, is not disposed on a backside of the substrate, and is readable by optical character recognition equipment. By placing the scribe mark within the edge exclusion zone of the substrate, in this manner, none of the space for salable dice is taken by the scribe mark. Further, the small size of the scribe mark reduces effects from chemical streaming, chemical mechanical polishing, and particulate expulsion. In addition, standard optical character recognition equipment can be used to read the scribe mark, without rendering the equipment unable to read prior art scribe marks.

### FIELD

This invention relates to the field of integrated circuit fabrication. More particularly, this invention relates to marking integrated circuit substrates.

### BACKGROUND

As the term is used herein, “integrated circuit” includes devices such as those formed on monolithic semiconducting substrates, such as those formed of group IV materials like silicon or germanium, or group III-V compounds like gallium arsenide, or mixtures of such materials. The term includes all types of devices formed, such as memory and logic, and all designs of such devices, such as MOS and bipolar. The term also comprehends applications such as flat panel displays, solar cells, and charge coupled devices.

Modem integrated circuits are typically fabricated on substrates, such as semiconducting substrates. In order to identify and track the substrates through the process, integrated circuit manufactures employ a identifying mark known as a scribe mark on each substrate. The exact nature of the mark varies from company to company, but the practice is sufficiently standard that standards bodies, such as Semiconductor Equipment and Materials International (SEMI), promulgate industry standards for substrate marking, such as the SEMI M-12 and M13 standards.

As the cost of manufacturing and the value of the dice on a substrate have increased, so has the need for tracking substrates via the substrate scribe. Most integrated circuit fabricators now employ some form of automatic scribe reading, such as optical character recognition (OCR), using a camera that is mounted to a substrate handling tool. The substrate scribe marks themselves are typically applied such as by using a laser marking system that burns pits into the substrate. A matrix of pits is commonly used to form standard characters that are readable by either OCR systems or the human eye.

The requirements for accurate material tracking and identification has driven the requirements for substrate scribe OCR readability to very high levels for every one of the over three hundred different manufacturing steps. In order to achieve this level of readability, the substrate scribe pits must be of a minimum depth to preserve contrast as layers are added and then filled in during the process.

At the same time as the scribe reading accuracy and reliability requirements are increasing, there is a growing recognition of the cost in potential die and die yield losses that the substrate scribe itself causes. This issue is driven by two factors, being (1) the area of the substrate that the substrate scribe uses, which could otherwise be used for salable die, and (2) particle and other types of defects that originate from the substrate scribe due to materials that collect or react there during processing.

For example, the laser scribing of the over five hundred dots that are typically used in a scribe mark can create defects known as slag, which must be cleaned off of the substrate. The deep scribe dots that are needed to maintain readability can interfere with the smooth flow of chemicals during wet cleaning operations, and can result in a chemical streak or poor substrate drying near the substrate scribe. Extra process steps are sometimes used to orient the substrate in certain directions relative to the chemical flow, to avoid such chemical streak issues.

Further, films that collect in the deep scribe dots can pop out at later steps and cause particle defects. Organic materials like photoresists are a particular problem in this respect In order to avoid popping defects from the substrate scribe, an extra resist exposure operation is sometimes used to remove resist over the scribe area and expose the underlying films for removal by subsequent etch processes. The large unpattemed scribe box and sharp step caused by the resist clear out causes poor chemical mechanical polishing planarity near the substrate scribe, so that the bottom row of dice do not yield well. There is no redundancy in the scribe number, so any damage to the scribe can render it unreadable. Also, as the substrate is processed, the scribe readability is degraded by the films that are repeatedly deposited in and over the scribe mark.

In addition, in the copper damascene processes that are used for 130 nanometer technologies and below, the practice of exposing the copper film to an etch to remove it over the substrate scribe does not work. This is because the copper lines are formed by filling trenches in the oxide layer rather than a subtractive etching of the metal film, as is done with aluminum based processes. Thus, many of the solutions to control the front side scribe will not work for damascene copper processes that do not use subtractive metal etch.

The relatively large area of copper film results in a large number of particle defects coming from the substrate scribe, which land on the rest of the substrate and reduce yields. This defect effect in copper processing is well known for causing defects from the edge of the substrate, and as a result the copper is typically removed from the edge of the substrate during or immediately after the copper plating operation. This copper edge removal process is applied concentrically around the edge of the substrate, but cannot remove the copper in the substrate scribe area.

Many companies that process three hundred millimeter substrates are now putting the substrate scribe on the back of the substrate. This tends to reduce some of the issues described above, since there are not as many films that build up on the back of the substrate, and the scribe does not consume usable silicon area on the front of the substrate. The problem with using a backside scribe, like that used for three hundred millimeter substrates, is that it is generally incompatible with existing two hundred millimeter substrate technologies. For example, many of the subcontractors that are used for assembly operations are not equipped to read backside scribes on two hundred millimeter substrates. Fabs that process two hundred millimeter substrates would have to modify or replace their substrate scribe reading equipment in order to use the backside mark. In many cases, a Fab would need to be able to read both a backside and front side mark in the same Fab at the same time, which would mean supporting two substrate scribe reading methods at the same time, and possibly require duplicate equipment.

Further, silicon suppliers that mark substrates would have to modify or replace their two hundred millimeter substrate marking and reading equipment to make and read the backside mark. In addition, they would need to be able to read both a backside and a front side mark in the same factory at the same time, which would mean supporting two substrate scribe reading methods at the same time, and possibly requiring duplicate equipment.

What is needed, therefore, is a substrate marking system that overcomes problems such as those described above, at least in part.

### SUMMARY

The above and other needs are met by a substrate that is adapted for the fabrication of integrated circuits, having an improved scribe mark. The scribe mark is small enough to fit within an edge exclusion zone of the substrate, is disposed wholly within the edge exclusion zone of the substrate, is not disposed on a backside of the substrate, and is readable by optical character recognition equipment.

By placing the scribe mark within the edge exclusion zone of the substrate, in this manner, none of the space for salable dice is taken by the scribe mark. Further, the small size of the scribe mark reduces effects from chemical streaming, chemical mechanical polishing, and particulate expulsion. In addition, standard optical character recognition equipment can be used to read the scribe mark, without rendering the equipment unable to read prior art scribe marks.

In various embodiments, the scribe mark is also disposed wholly within a copper edge removal zone of the substrate. In some embodiments, the scribe mark is in all other respects a SEMI T-7 scribe mark. Preferably, the scribe mark is no larger than about one millimeter by about four millimeters. The scribe mark is preferably a laser ablated mark on the substrate. The scribe mark may alternately be disposed on a bevel of the substrate, or at about a ninety degree point at an edge of the substrate. In some embodiments, more than one of the scribe marks are disposed on the substrate. Most preferably, the scribe mark is disposed wholly within an area of about a two millimeter circumference from an edge of the substrate. The substrate is preferably formed of at least one of silicon, germanium, and gallium arsenide.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a comparison of a standard scribe mark and a scribe mark according to a preferred embodiment of the present invention.

FIG. 2 depicts the location on a substrate of a standard scribe mark and a scribe mark according to a preferred embodiment of the present invention.

### DETAILED DESCRIPTION

One feature of the preferred embodiments of the present invention is to use a much smaller substrate scribe 12 that is placed wholly within the outer two millimeters or so of the substrate 14, in what is known as the substrate edge exclusion zone 16. This puts the substrate scribe 12 in the edge area where copper can be removed, overcoming one of the problems described above, yet keeping the scribe 12 on the front of the substrate where existing two hundred millimeter OCR equipment can read it, overcoming another of the problems mentioned above. In addition, the scribe location and size makes a significant amount of surface area on the substrate 14, which was formerly used for the old substrate scribe 10, newly available for production dice, thus overcoming yet another problem described above.

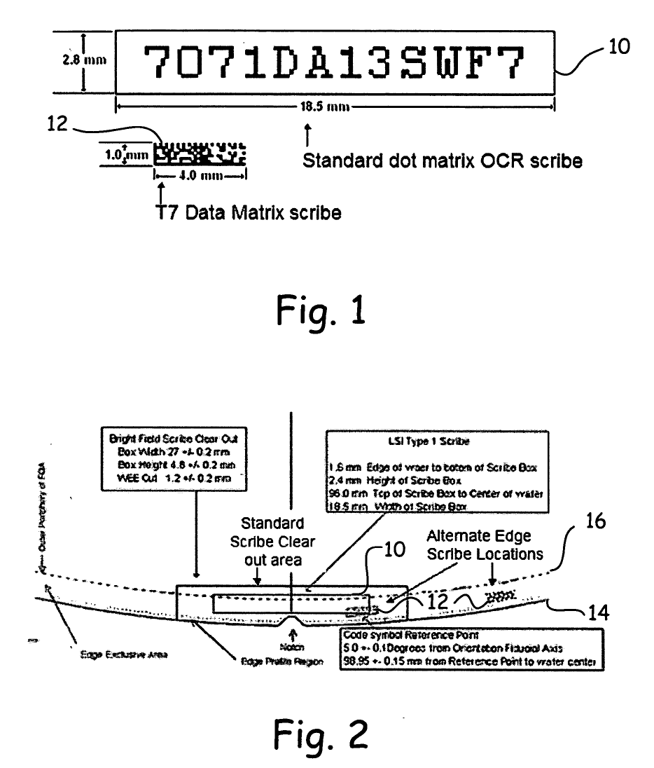

Many different embodiments of the smaller scribe mark 12 are contemplated hereunder. For example, SEMI has a scribe standard called the T-7 scribe, which is placed on the back of a three hundred millimeter substrate. The T7 scribe is a rectangular, two-dimensional, machine-readable, binary data matrix code that has a very small total scribe area, with data redundancy. Up to thirty percent of the T7 data can be missing, and all of the scribe information can still be read, as described in SEMI standard T7-030-2002. FIG. 1 depicts a comparison of the T7 scribe 12 and a standard scribe 10.

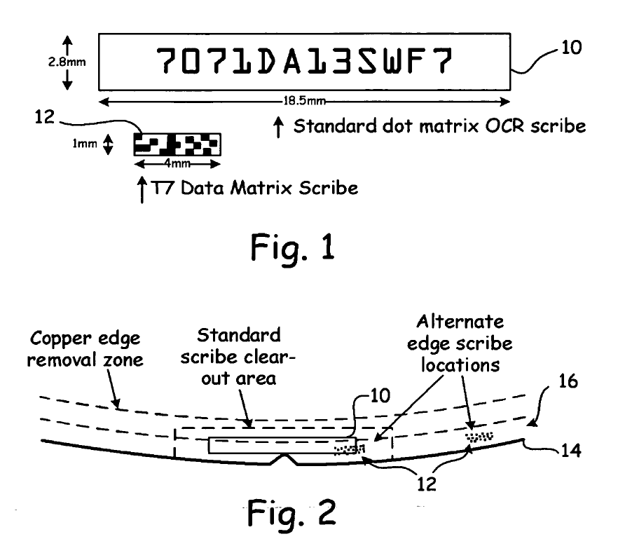

Preferably, a small format scribe 12 like the T7 is used in the embodiments of the present invention, but it is placed on the front or the edge of the substrate 14 rather than on the back. In one embodiment the scribe mark 12 is placed at about 1.05 millimeters from the edge of the substrate 14. Preferably, the scribe mark 12 is within both the edge exclusion area 16 of the substrate 14 and the copper edge removal zone. The scribe 12 is preferably readable with standard two hundred millimeter OCR systems. FIG. 2 depicts the placement of the prior art scribe 10 clear out window and possible locations for a small format edge scribe 12 within the edge exclusion area 16. In various embodiments, multiple small scribes 12 are placed around the edge of the substrate 14 for additional data redundancy.

The various embodiments of the present invention have many benefits over the prior art. These embodiments generally increase the saleable die area of the substrate 14 by eliminating large front side scribes 10. The time and cost for clearing resist from the substrate 14 scribe area is reduced. Data redundancy is provided, in comparison to a standard front side scribe 10. Scribe markings 12 are placed farther away from salable dice, and thus particle defects and chemical mechanical polishing effects are reduced. The smaller scribe 12 area is less likely to interfere with chemical flows in wet cleaning operations.

The scribes 12 are disposed in an edge zone 16 of the substrate 14 where copper films can be removed. The new scribes 12 can be read with standard two hundred millimeter front side OCR equipment. The same two hundred millimeter OCR equipment can read both the new edge scribe 12 and the standard front side scribes 10, with only a software setting change. The substrate scribe 12 is placed in an area of the substrate 14 where chemical solvent resist removal is used, so resist is fully removed from any deep scribe dots. The scribe holes will have less films deposited into them, particularly tungsten films, so shallower dot depths can be used while still retaining scribe readability.

In one embodiment, the small format edge scribe 12 is placed further around the edge of the substrate 14, such as on the bevel or at the ninety degree point of the substrate 14 edge. This may require some modification to both substrate scribe and OCR reading equipment, but further reduces the occurrence of defects coming from the scribe 12, by putting the scribe 12 farther away from the active die area, and further reducing films that deposit on the scribe 12. This invention disclosure uses the T7 scribe mark as an example of a usable small format scribe 12, but it is appreciated that any small format scribe 12 could be used, so long as it will fit in the edge exclusion area 16 and can be read by OCR equipment.

The foregoing description of preferred embodiments for this invention has been presented for purposes of illustration and description. It is not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

1. A substrate adapted for the fabrication of integrated circuits, the improvement comprising a scribe mark, where the scribe mark:
is disposed wholly within an edge exclusion zone of the substrate on the frontside of the substrate,
is not disposed on a backside, bevel, or edge of the substrate, and
is readable by optical character recognition equipment.

2. The substrate of claim 1, wherein the edge exclusion zone of the substrate is disposed in a ring around the substrate that extends from the edge of the substrate inward about two millimeters toward a center of the substrate.

3. The substrate of claim 1, wherein the scribe mark is a two dimensional binary data matrix.

4. The substrate of claim 1, wherein the scribe mark is no larger than about one millimeter by about four millimeters.

5. The substrate of claim 1, wherein the scribe mark is a laser ablated mark on the substrate.

6. The substrate of claim 1, wherein the scribe mark is disposed no closer than about one millimeter from the edge of the substrate.

7. (canceled)

8. The substrate of claim 1, wherein more than one of the scribe marks are disposed on the substrate.

9. The substrate of claim 1, wherein the substrate is formed of at least one of silicon, germanium, and gallium arsenide.

10. (canceled)

11. (canceled)

12. (canceled)

13. (canceled)

14. (canceled)

15. (canceled)

16. (canceled)

17. (canceled)

18. (canceled)

19. (canceled)

20. (canceled)
